(19) United States
(12) Patent Application Publication
(10) Pub. No.: US 2024/0017987 A1
(43) Pub. Date: Jan. 18, 2024

(54) Anchor Structure

(71) Applicant: SENSORTEK TECHNOLOGY CORP., Hsinchu County (TW)

(72) Inventors: Shih-Wei Lee, Hsinchu County (TW); Kuan-Ju Tseng, Hsinchu County (TW); Chao-Shiun Wang, Hsinchu County (TW)

(21) Appl. No.: 18/129,911

(22) Filed: Apr. 3, 2023

Related U.S. Application Data
(60) Provisional application No. 63/326,440, filed on Apr. 1, 2022.

(51) Int. Cl. B81B 3/00; B81C 3/00

(52) U.S. Cl. CPC B81B 3/0072; B81C 3/001; B81B 2203/0307; B81C 2203/054

(57) ABSTRACT

The present application discloses an anchor structure for application to a microelectromechanical system device comprising a cap layer, a device layer and a substrate layer. Such an anchor structure enhances the stress tolerance of the microelectromechanical system device. The anchor structure comprises a first anchor portion, a second anchor portion and a flexible member located in the device layer. The first anchor portion and the second anchor portion are connected to two sides of the flexible member, respectively. The first anchor is secured to the cap layer by a first bonding portion, and the second anchor is secured to the substrate layer by a second bonding portion.

### FIELD OF THE INVENTION

The present application is related to an anchor structure, in particular to an anchor structure applied for a microelectromechanical system (MEMS).

### BACKGROUND OF THE INVENTION

A microelectromechanical system device (hereinafter called MEMS device) is normally formed by a cap layer on the top, a device layer at the middle, and a substrate layer at the bottom. An anchor structure is a fixed point in the structure used for supporting the other structures of the device. It can be used as a fulcrum for the movement of the other structures and even should be connected to the cap layer, the device layer, and the substrate layer for fixing them. Anchor structures are especially important for maintaining the structural integrity of devices and avoiding accidental movement or deformation of the structures hanging inside the device. The design and arrangement of anchor structures can significantly influence the performance and reliability of MEMS devices.

A general anchor structure is connected with the cap layer and the substrate layer by both sides of an anchor point disposed in the device layer. Although the fixing structure from both sides can form a stable structure by clamping, it is vulnerable to stress from the cap layer or the substrate layer. For example, stress can be formed from the deformation caused by temperature variation or external force. Assume the stress only acts at the cap layer in the initial. Since both sides of the anchor point are connected to the cap layer and the substrate layer, respectively, the stress will definitely be transferred to the substrate layer, or vice versa. Then, the stress will affect the overall MEMS device via the anchor structure. Once the stress is excessive, it will possibly led to the signals from the MEMS device containing offset.

Unfortunately, for MEMS devices, the stress is unavoidable. For example, while soldering and fixing a MEMS device to a printed circuit board (PCB), the stress is applied to the MEMS device by the temperature difference between PCB, solder balls and device packaging materials. In addition, if a MEMS device is installed to a portable electronic device, it will bear external force in the usage process. Accordingly, how to make a MEMS device not sensitive to stress becomes extremely important.

### SUMMARY OF THE INVENTION

The present application provides an improved anchor structure for solving the influence of stress in the overall MEMS device via the anchor structure.

To achieve the above objective, the present application provides an anchor structure, which can be applied to a MEMS device including a cap layer, a device layer, and a substrate layer. The anchor structure comprises a first anchor part in the device layer, a second anchor part, and a flexible element. The first anchor part and the second anchor part are connected to both sides of the flexible element, respectively. The first anchor part is fixed to the cap layer via a first bonding part. The second anchor part is fixed to the substrate layer via a second bonding part.

By adopting the anchor structure with the first anchor and the second anchor part connecting to the cap layer and the substrate layer, respectively, the stress transfer between the cap layer and the substrate layer can be reduced. Even under higher stress, the occurrence of signal offset is minimal, thus further enhancing product reliability.

### BRIEF DESCRIPTION OF DRAWINGS

FIG. 1 shows a cross-sectional view of the anchor structure according to the first embodiment of the present application;

FIG. 2A shows a top view of elements including the anchor structure according to the second embodiment of the present application;

FIG. 2B shows a cross-sectional view along the cutline A-A′ in FIG. 2A;

FIG. 3 shows a top view of the elements including the anchor structure according to the third embodiment of the present application; and

FIG. 4 shows a cross-sectional view of the anchor structure according to the fourth embodiment of the present application.

### DETAILED DESCRIPTION OF THE INVENTION

In order to make the structure and characteristics as well as the effectiveness of the present application to be further understood and recognized, the detailed description of the present application is provided as follows along with embodiments and accompanying figures.

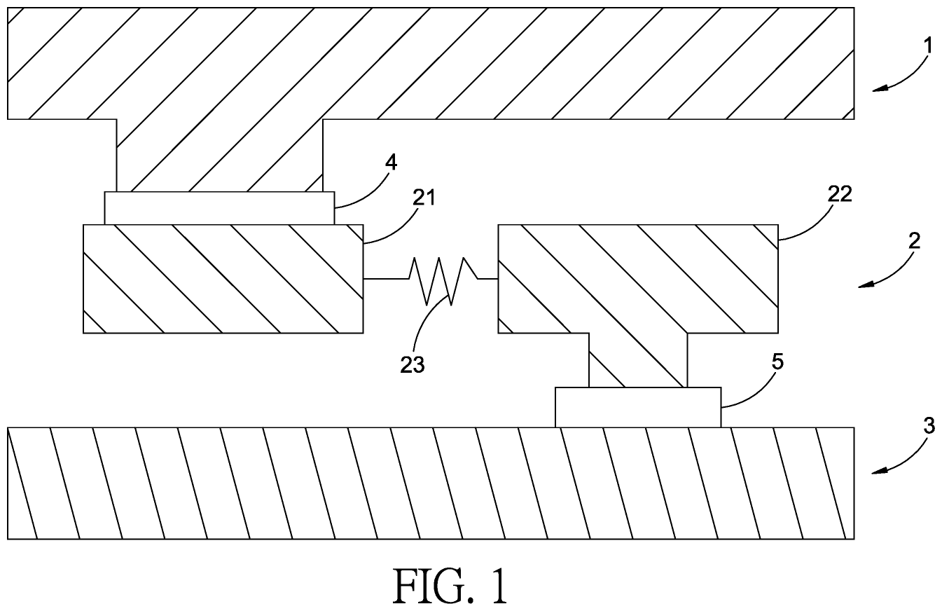

Please refer to FIG. 1, which shows a cross-sectional view of the anchor structure according to the first embodiment of the present application. The anchor structure according to the present application is applied to a MEMS device including a cap layer 1, a device layer 2, and a substrate layer 3. The anchor structure comprises a first anchor part 21 in the device layer 2, a second anchor part 22, and a flexible element 23. The first anchor part 21 is fixed to the cap layer 1; the second anchor part 22 is fixed to the substrate layer 3. In other words, the first anchor part 21 is not fixed to the substrate layer 3 and the second anchor part 22 is not fixed to the cap layer 1.

The flexible element 23 is a flexible structure with an easily deformable structure. In a MEMS device, due to cost concern, the selectable materials are generally limited. One possible way is to adopt the same material to fabricate the first anchor part 21, the second anchor part 22, and the flexible element 23. The flexible element 23 can be designed to have a smaller cross-sectional area for forming a flexible structure. Of course, if it is permitted by the fabricating process, a material different from the first anchor part 21 and the second anchor part 22 can be selected to fabricate the flexible element 23. Alternatively, if the space is sufficient, the flexible element 23 can be designed to have one or more bending part and equivalently form a spring structure.

The first anchor part 21 is fixed to the cap layer 1 via a first bonding part 4. The second anchor part 22 is fixed to the substrate layer 3 via a second bonding part 5. The anchor structure according to the first embodiment of the present application can also act as the fulcrum in the MEMS device and is connected to the cap layer 1 and the substrate layer 3, respectively. Nonetheless, unlike the prior art, the cap layer 1 and the substrate layer 3 are not connected to both sides of an anchor point. Instead, they are connected to the first anchor part 21 and the second anchor part 22, respectively. In addition, the first anchor part 21 and the second anchor part 22 are connected via the flexible element 23. Thereby, the flexible element 23 can reduce the stress transfer between the cap layer 1 and the substrate layer 3 significantly.

For example, when the cap layer 1 is influenced by stress, the stress will be attenuated by the flexible element 23 before being transferred to the second anchor part 22 and hence lowering the influence of the stress on the substrate layer 3. Besides, the second anchor part 22 can be used to hang the structures inside the MEMS device, such as sensors or actuators. Thereby, likewise, the influence of the stress of the cap layer 1 on these structures can be avoided. In other words, the influence of the stress or deformation of the cap layer 1 on the substrate layer 3 can be reduced. Accordingly, by using the anchor structure according to the first embodiment of the present application, when a MEMS device is influenced by stress, the possibility of signal offset can be lowered effectively and hence further improving product reliability.

In practice, there are many methods to fabricate the anchor structure according to the first embodiment. In the following, a fabrication method is used to illustrate the overall fabrication process. Nonetheless, it is not to limit the method for fabricating the anchor structure according to the present application.

A fabrication method for MEMS device comprises a first bonding step and a second bonding step. The first bonding step is to fabricate the first bonding part 4 for connecting the first anchor part 21 and the cap layer 1. The second bonding step is to fabricate the second bonding part 5 for connecting the second anchor part 22 and the substrate layer 3. The first bonding step and the second bonding step can be any wafter bonding process according to the prior art, for example, direct bonding, anodic bonding, eutectic bonding, adhesive bonding, and thermocompression bonding.

The detailed fabrication steps include connecting the first anchor part 21 and the second anchor part 22 to both sides of the flexible element 23, respectively and connecting the first anchor part 21 and the cap layer 1 using the first bonding step. At this moment, the first anchor part 21 and the flexible element 23 can be used as a temporary frame for hanging the second anchor part 22 and maintaining the second anchor part 22 at the predetermined location. Next, use the second bonding step to connect the second anchor part 22 and the substrate layer 3. In a general bonding process, two objects to be bonded should be pressed. However, the cap layer 1 and the second anchor part 22 do not contact. Thereby, the force from the cap layer 1 cannot be directly applied to the second anchor part 22 for approaching the substrate layer 3. Nonetheless, when the cap layer 1 approaches the substrate layer 3, the first anchor part 21 can drive the second anchor part 22 via the flexible element 23 to approach the substrate layer 3 to form a bonding force, and thus fabrication of the second bonding part 5 is completed.

It should be noted that the magnitude of the bonding force applied to the second anchor part 22 via the flexible element 23 is influenced by the rigidity of the flexible element 23. If the flexible element 23 is more rigid, the bonding force applied to the anchor part 22 is larger. Meanwhile, the coupling force between the first anchor part 21 and the second anchor part 22 is greater. In general, to reduce stress transfer between the cap layer 1 and the substrate layer 3, the coupling force between the first anchor part 21 and the second anchor part 22 should be kept low. Accordingly, how to design the rigidity of the flexible element 23 depends upon user requirements and parameters of the bonding process.

On the other hand, if the first bonding step and the second bonding step are high-temperature processes such as eutectic bonding or thermocompression bonding, the operating temperature of the first bonding step (roughly the melting point of the first bonding part 4) can be chosen to be higher than the operating temperature of the second bonding step (roughly the melting point of the second bonding part 5). Thereby, while fabricating the second bonding part melting and deformation at the first bonding part 4 can be avoided.

The above example is only one of the fabrication methods to implement the anchor structure according to the first embodiment. In practice, in other possible fabrication methods, the second anchor part 22 is connected to the substrate layer 3 before connecting the first anchor part 21 to the cap layer 1. Alternatively, connecting the second anchor part 22 to the substrate layer 3 can be performed concurrently with connecting the first anchor part 21 to the cap layer 1. No matter what fabrication method is adopted, since the first anchor part 21 and the second anchor part 22 of the anchor structure according to the first embodiment are connected to both sides of the flexible element 23, it is guaranteed that the first anchor part 21 and the second anchor part 22 can be fixed to the cap layer 1 and the substrate layer 3, respectively. To be specific, if the second anchor part 22 and the substrate layer 3 are connected first, although the substrate layer 3 cannot force the first anchor part 21 to approach the cap layer 1 directly because the substrate layer 3 does not contact the first anchor part 21, when the substrate layer 3 approaches the cap layer 1, the second anchor part 22 can drive the first anchor part 21 via the flexible element 23 for approaching the cap layer 1 to form a bonding force. Thereby, fabrication of the first bonding part 4 can be completed.

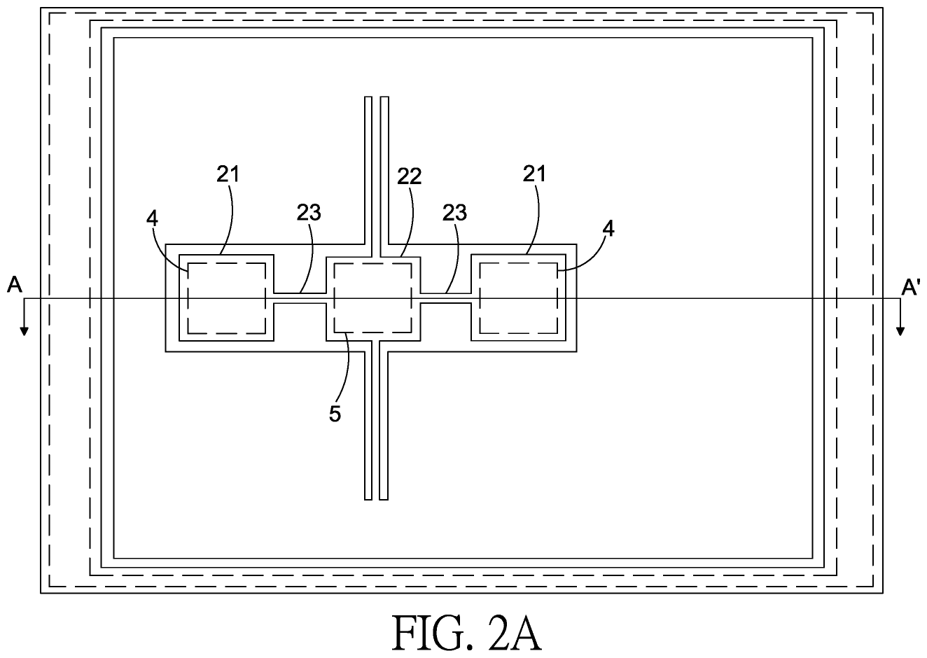

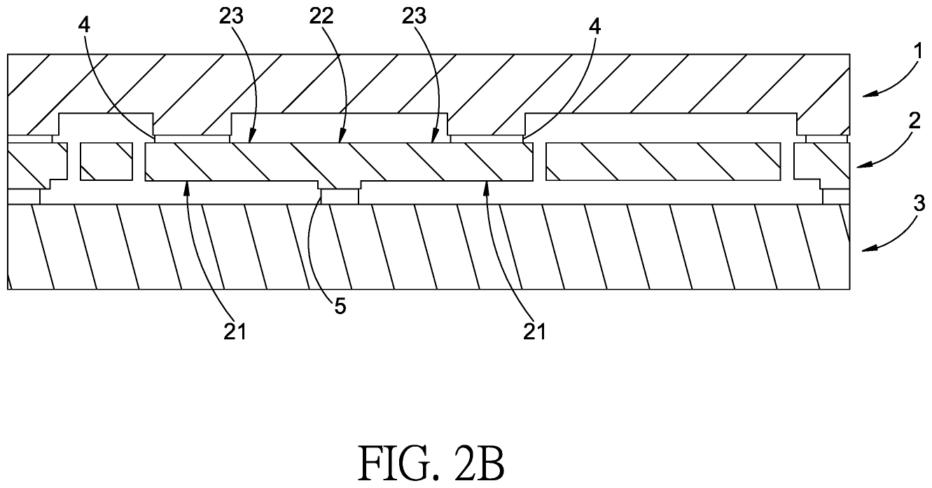

In the previous embodiment, only the anchor structure itself is described. Nonetheless, in practice, there are other corresponding structures in a MEMS device. They will be described in the following example. Please refer to FIG. 2A and FIG. 2B. FIG. 2A shows a top view of the device including the anchor structure according to the second embodiment of the present application; FIG. 2B shows a cross-sectional view along the cutline A-A′ in FIG. 2A.

The major difference between the anchor structure according to the second embodiment and the one according to the first embodiment is that, according to the present embodiment, two first anchor parts 21 are adopted. The two first anchor parts 21 are connected to the periphery of the second anchor part 22 via two flexible elements 23. Thereby, when the cap layer 1 approaches the substrate layer 3, the two first anchor parts 21 can drive the second anchor part 22 via the flexible elements 23 to form a uniform bonding force. Likewise, according to another embodiment, three or more first anchor parts 21 and the corresponding amount of the flexible elements 23 can be adopted.

In addition, according to the present embodiment, the first anchor part 21, the second anchor 22, and the flexible element 23 can be fabricated using the same material. Nonetheless, the flexible element 23 is designed to have a smaller cross-sectional area to form the flexible structure. The advantage of this method is that the first anchor part 21, the second anchor 22, and the flexible element 23 can be fabricated concurrently in the device layer 2, which is apparently beneficial to save process costs.

The first anchor part 21 or the second anchor 22 can be used for hanging the internal structures of a MEMS device. For example, it can be observed in FIG. 2A that the second anchor part 22 can be used to hang a rotational axis structure so that the MEMS device can form a teeter-totter type Z-axis accelerometer. Here, the operation principle of a MEMS accelerometer will not be described. As described above, since the anchor structure according to the second embodiment is adopted, when the cap layer 1 is influenced by stress, the influence of the stress on the substrate layer 3 will be lowered. Likewise, when the substrate layer 3 is influenced by stress, the influence of the stress on the cap layer 1 and the structure hanging on the first anchor part 21 will be reduced.

Moreover, it can be noted that a ring structure connected to the cap layer 1 and the substrate layer 3, respectively, is disposed surrounding the MEMS device. Nonetheless, this is a frame portion of the MEMS device, not the anchor structure of the present application.

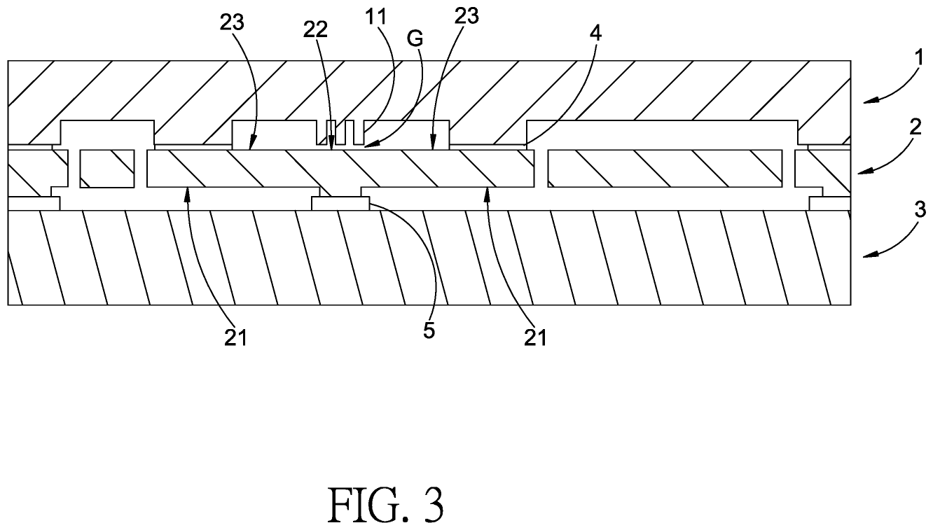

Please refer to FIG. 3, which shows a top view of the device including the anchor structure according to the third embodiment of the present application. The difference between the third embodiment and the second is that, according to the present embodiment, the cap layer 1 includes an auxiliary rib part 11, which can include one or more ribs projecting toward the device layer 2. Besides, the auxiliary rib part 11 is aligned to the second anchor part 22 with a gap G. To elaborate, in the process of connecting the second anchor part 22 and the substrate layer 3 using the second bonding step, when the force applied to the cap layer 1 is large enough to have deformation greater than the gap G, the auxiliary rib part 11 will contact the second anchor part 22 for facilitating the second anchor part 22 to press the substrate layer 3 and forming a bonding force. Once completed fabricating the second bonding part 5 and stopping the force applied to the cap layer 1, the auxiliary rib part 11 will restore to maintain the gap G with respect to the second anchor part 22. Thereby, the anchor structure according to the third embodiment can also reduce stress transfer between the cap layer 1 and the substrate layer 3.

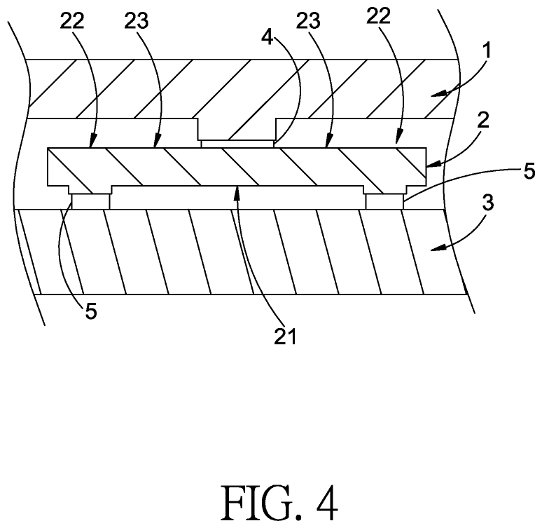

Please refer to FIG. 4, which shows a cross-sectional view of the anchor structure according to the fourth embodiment of the present application. The difference between the fourth embodiment and the first one is that, according to the present embodiment, two second anchor parts 22 are adopted. The two second anchor parts 22 are connected to the periphery of the first anchor part 21. Thereby, when the cap layer 1 approaches the substrate layer 3, the first anchor part 21 can drive the two second anchor parts 22 via the flexible element 23 to form a uniform bonding force. Likewise, according to another embodiment of the present application, three or more second anchor parts 22 and the corresponding amount of the flexible element 23 can be adopted.

To sum up, the MEMS devices according to the prior art adopt an anchor point structure with fixed both sides, making it less tolerable to stress. The present application improves by providing an anchor structure comprising the first anchor part 21 and the second anchor part 22 connecting to the cap layer 1 and the substrate layer 3, respectively. In addition, the first anchor part 21 and the second anchor part 22 are connected via the flexible element 23. The flexible element 23 can reduce stress transfer between the cap layer 1 and the substrate layer 3 significantly. Thereby, the bad influence of stress on MEMS devices can be avoided and thus further improving product reliability.

It should be emphasized again that although in FIG. 1 to FIG. 4, the flexible element 23 are simplified to represent by a columnar member with the same material as the first anchor part 21 and the second anchor part 22, in practice, a person having ordinary skill in the art should know that the flexible element 23 can be a zig-zag flexible structure as well. Alternatively, the flexible element 23 can be fabricated using a material different from the material of the first anchor part 21 or the second anchor part 22. Thereby, the designer can modify the center of mass, the elasticity coefficient, and the deformation of the flexible element 23.

Accordingly, the present application conforms to the legal requirements owing to its novelty, nonobviousness, and utility. However, the foregoing description is only embodiments of the present application, not used to limit the scope and range of the present application. Those equivalent changes or modifications made according to the shape, structure, feature, or spirit described in the claims of the present application are included in the appended claims of the present application.

1. An anchor structure, applied to a microelectromechanical system device including a cap layer, a device layer, and a substrate layer, comprising:
a first anchor part, located in said device layer;
a second anchor part, located in said device layer; and
a flexible element, located in said device layer;
where said first anchor part and said second anchor part are respectively connected to both sides of said flexible element; said first anchor part is fixed to said cap layer via a first bonding part; and said second anchor part is fixed to said substrate layer via a second bonding part.

2. The anchor structure of claim 1, wherein said first anchor part is not fixed to said substrate layer and said second anchor art is not fixed to said cap layer.

3. The anchor structure of claim 1, wherein said cap layer includes an auxiliary rib part; said auxiliary rib part is aligned to said second anchor part; and said auxiliary rib part and said second anchor part are spaced by a gap.

4. The anchor structure of claim 1, further comprising another first anchor part and another flexible element, and said two first anchor parts being connected to the periphery of said second anchor part via said two flexible elements.

5. The anchor structure of claim 1, further comprising another second anchor part and another flexible element, and said two second anchor parts being connected to the periphery of said first anchor part via said two flexible elements.

6. The anchor structure of claim 1, wherein said first anchor part, said second anchor part, and said flexible element are fabricated using the same material; and the cross-sectional area of said flexible element is smaller than the cross-sectional area of said first anchor part and said second anchor part.

7. The anchor structure of claim 1, wherein the melting point of said first bonding part is higher than the melting point of said second bonding part.

8. The anchor structure of claim 1, wherein the melting point of said first bonding part is lower than the melting point of said second bonding part.

9. The anchor structure of claim 1, wherein said second anchor pat is configurable for hanging the internal structures of said microelectromechanical system device.

10. The anchor structure of claim 1, wherein said first anchor pat is configurable for hanging the internal structures of said microelectromechanical system device.
